(19) United States
(12) Patent Application Publication
(10) Pub. No.: US 2008/0144296 A1
(43) Pub. Date: Jun. 19, 2008

(54) Press stripe device for computer interface card

(76) Inventor: Wei-Ping Chen, Taipei (TW)

Correspondence Address: WEI-PING CHEN, 235 Chung - Ho, Box 8-24, Taipei, omitted

(21) Appl. No.: 11/640,521

(22) Filed: Dec. 18, 2006

(51) Int. Cl. H05K 5/02

(52) U.S. Cl. 361/759

(57) ABSTRACT

A press stripe device for a computer interface card comprises a casing body; at least one press stripe locating above the casing body; the press stripe having a plurality of guide channels; each of two sides of the guide channel having a plurality of slots; at least one press unit formed of a bracket and a suspending arm which is pivotally installed to the bracket; the bracket having a block corresponding to the guide channel and at least one downward extending rotary shaft; the suspending arm having an ear corresponding to the slot of the press stripe and sliding grooves at two sides thereof; and wherein the press unit is engaged to the press stripe by the block being locked to a lower side of the press stripe so that the bracket is moveable to drive the suspending arm of the bracket.

### FIELD OF THE INVENTION

The present invention relates to press stripes for a computer interface card, and particularly to a press stripe device for a computer interface card, wherein a greater adjustment margin is provided so that a suspending arm of a press unit has a great angle for adjustment.

### BACKGROUND OF THE INVENTION

An industry computer has a bus architecture for detecting and controlling electronic products, which is like a computer, and includes a computer processor, a hard disk, a memory, an interface card, an operation system, a network and related protocols, computing ability and friendly human-machine interfaces. Generally the software used in industry computer are identical to that used in general computers so as to reduce the burden in updating, promotion, and maintenance. The industry computer includes a casing, a bottom plate, interface cards, etc.

In the structure of machine frame, the arrangement of the industry compute is flexible for providing interface cards of different sizes. In one prior art about the press stripe of a computer interface cards, as illustrated in FIG. 9 of the present invention, a back plate 11 of a casing 10 has a plurality of interface cards 12 for matching to various operation requirements in industry computers. The casing 10 has a press stripe 13. A lateral side of the press stripe 13 has a plurality of through holes. A press unit 14 used with the press stripe 13 has a long groove 140 and a pad 141 at a lower side thereof. The press unit 14 is inserted into the through hole. Then the press unit 14 slides to be above the interface card 12. Screw units are used to lock the press unit 14 to the lateral side of the press stripe 13 so as to press the interface card 12 for avoiding bad contact between the motherboard and the interface card 12 due to vibration and thus the control sequences will disorder.

However, this prior art has the following disadvantages. Firstly, the press stripe must be made based on the elevation difference between the interface card and the press stripe, however, the adjusting margin of the press stripe is insufficient. When the press stripe is not suitable, it can not be pressed correctly. The pressure from the press stripe to the interface card must be proper. A too great or tool small force is not suitable. Furthermore the operation for displacing the press stripe is not smooth. One hand serves to move the press stripe and another hand serves to guide it in lateral direction. The control force is insufficient.

### SUMMARY OF THE INVENTION

Accordingly, the primary object of the present invention is to provide a press stripe device for a computer interface card, wherein a great adjustment margin is provided so that a suspending arm of a press unit has a great angle for adjustment. Thereby the specification of the press unit can be unified so that the cost in manufacturing is reduced greatly. Furthermore in the present invention, the suspending arm of the bracket is adjustable in a guide channel of a press stripe continuously so that the interface card can be well positioned.

To achieve above objects, the present invention provides a press stripe device for a computer interface card, wherein A press stripe device for a computer interface card comprises a casing body; at least one press stripe locating above the casing body; the press stripe having a plurality of guide channels; each of two sides of the guide channel having a plurality of slots; at least one press unit formed of a bracket and a suspending arm which is pivotally installed to the bracket; the bracket having a block corresponding to the guide channel and at least one downward extending rotary shaft; the suspending arm having an ear corresponding to the slot of the press stripe and sliding grooves at two sides thereof; and wherein the press unit is engaged to the press stripe by the block being locked to a lower side of the press stripe so that the bracket is moveable to drive the suspending arm of the bracket.

The various objects and advantages of the present invention will be more readily understood from the following detailed description when read in conjunction with the appended drawing.

### BRIEF DESCRIPTION OF THE DRAWINGS

FIG. 1 is an exploded view of the computer casing of the present invention.

FIG. 2 is an elevational view of the computer casing of the present invention.

FIG. 3 is a structural schematic view of the present invention.

FIG. 4 is an exploded view of the press unit of the present invention.

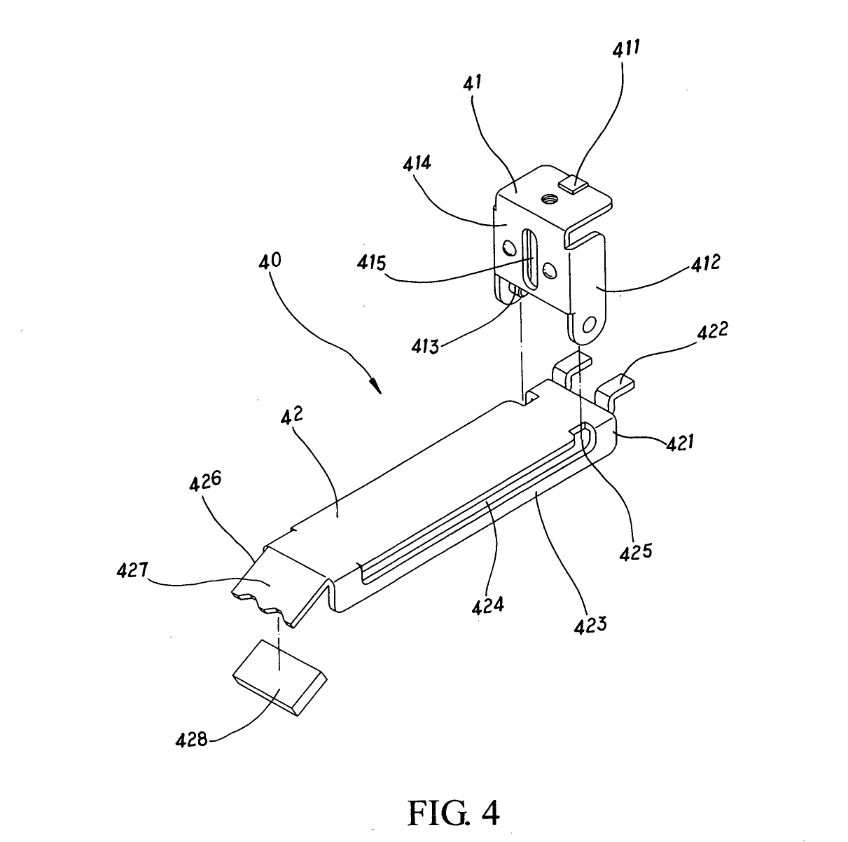

FIG. 5 is a schematic view about the interface card of the present invention.

FIG. 6 is a schematic view showing the moving range of the present invention.

FIG. 7 is a schematic view showing the movement of the bracket on the press stripe according to the present invention.

FIG. 8 shows another embodiment of the present invention.

FIG. 9 shows a prior art about the present invention.

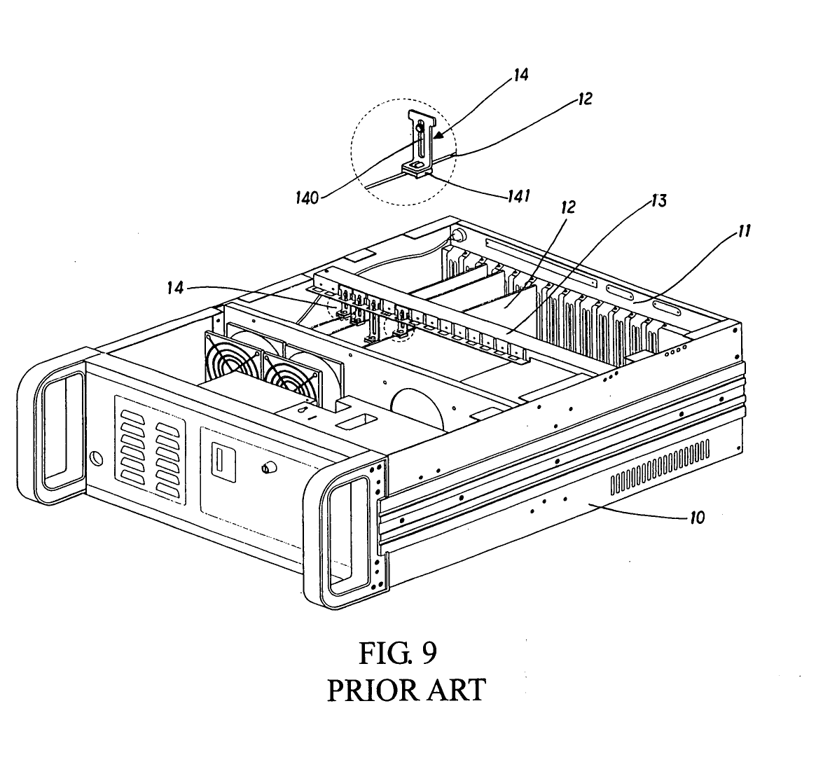

### DETAILED DESCRIPTION OF THE INVENTION

In order that those skilled in the art can further understand the present invention, a description will be provided in the following in details. However, these descriptions and the appended drawings are only used to cause those skilled in the art to understand the objects, features, and characteristics of the present invention, but not to be used to confine the scope and spirit of the present invention defined in the appended claims.

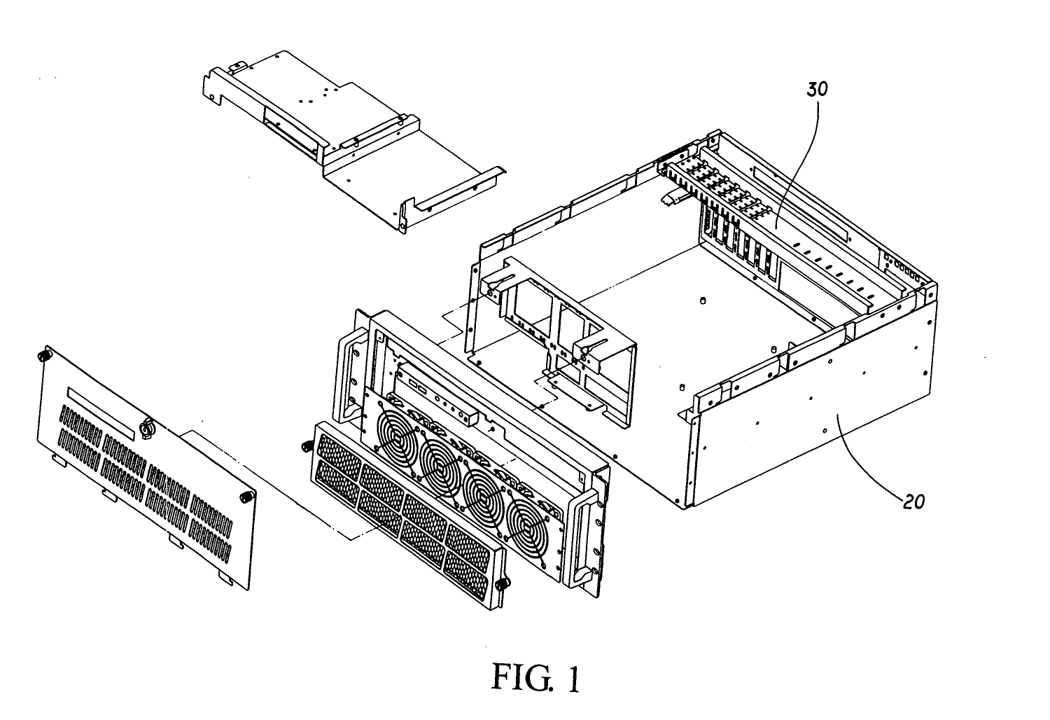

Referring to FIG. 1, the computer casing of the present invention has the following structure. A casing body 20 has a predetermined space for assembling a power source, a fan, a motherboard, an interface card, and others. In the present invention, the computer interface card press stripe 30 are placed upon the casing body 20 and above the interface card for pressing the interface card so as to avoid the vibration of the interface card 12 and thus not to be well in contact with the motherboard and to affect the control sequence. An upper cover (not shown) will covers upon the casing body 20.

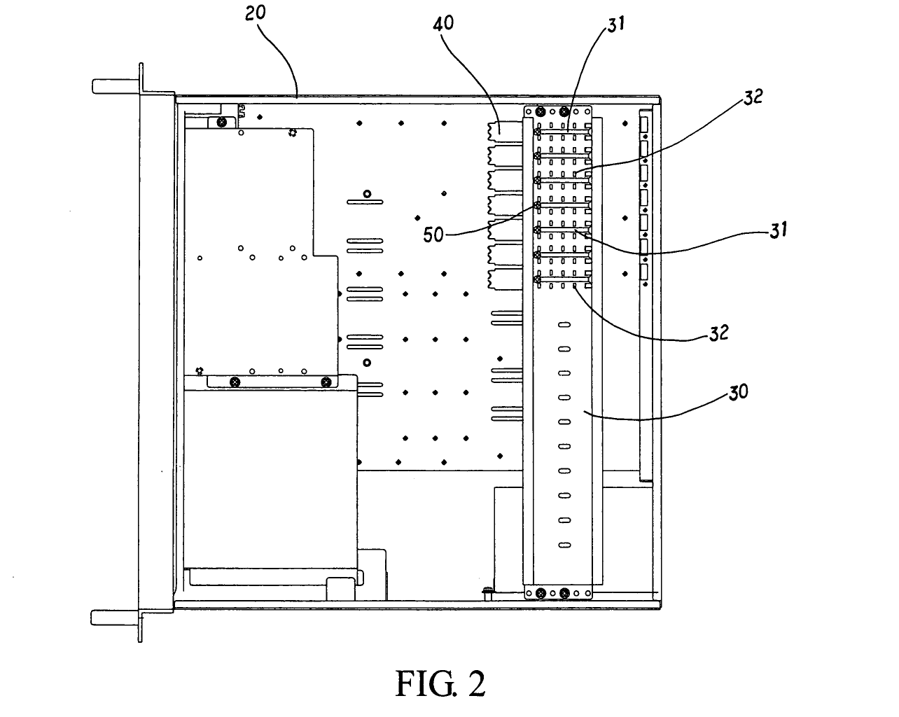

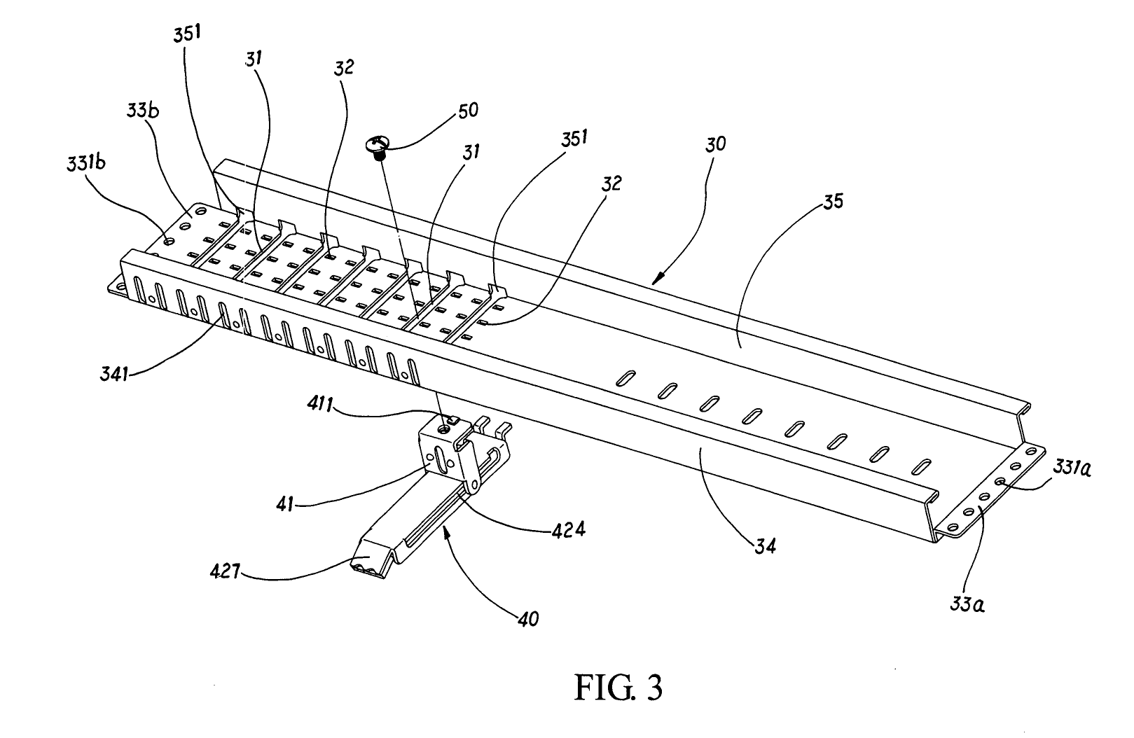

With reference to FIG. 2, one arrangement of the computer casing is illustrated. The press stripe 30 will be further discussed herein. In the drawing, the press stripe 30 runs cross the casing body 20. The press stripe 30 has a plurality of guide channels 31. Two sides of each guide channel 31 have a plurality of slots 32. The guide channels 31 are fixed by a plurality of locking elements 50. A press unit 40 is installed upon the press stripe 30. The press unit 40 can move along the press stripe 30. The detail will be described with reference to FIG. 3.

Two ends of the press stripe 30 have respective retaining ends 33a, 33b. The retaining end 33a has through holes 331a and the retaining end 33b has through holes 331b for connecting the press stripe 30 to the casing body 20. The design of the guide channels 31 on the press stripe 30 is based on the position of the interface card 12. In the drawing, seven guide channels 31 are installed. This means that the press stripe 30 can be assembled with seven press units 40. In the application of the present invention, the number and positions of the guide channel 31 are not confined to these. Others are permissible. A first wall 34 of the press stripe 30 is formed with a plurality of long grooves 341 for assembling the press units 40.

One end of each guide channel 31 has a via hole 351 which is at a second wall 35 of the press stripe 30.

The press unit 40 is formed by a bracket 41 and a suspending arm 42 which are pivotally connected. The bracket 41 has a guide block 41 at an upper surface thereof. The guide block 41 passes through the via hole 351 and then enters into the guide channel 31 so that in displacement, the press unit 40 can be retained in a correct locking position. Two lateral side of the bracket 41 are formed with respective extending ends 412. Each extending end 412 has a downward rotary shaft 413. A main wall 414 is formed between the two extending ends 412. The main wall 414 has a short slot 415. One end of the suspending arm 42 has an ear 422 which is corresponding to the upper slot of the press stripe 30. Each of two lateral sides of the suspending arm 42 has a sliding groove 424 which is corresponding to the rotary shaft 413 of the bracket 41. One end of the sliding groove 424 has an opening 425. The rotary shaft 413 of the bracket 41 enters into the sliding groove 424 from the opening 425 so that the bracket 41 is combined with the suspending arm 42 as the press unit 40. Another end 426 of the suspending arm 42 has an extension 427. A bottom of the extension 427 has a pad 428 which is compressible. Thereby in pressing an interface card, the pad can buffer the pressure applied to the interface card.

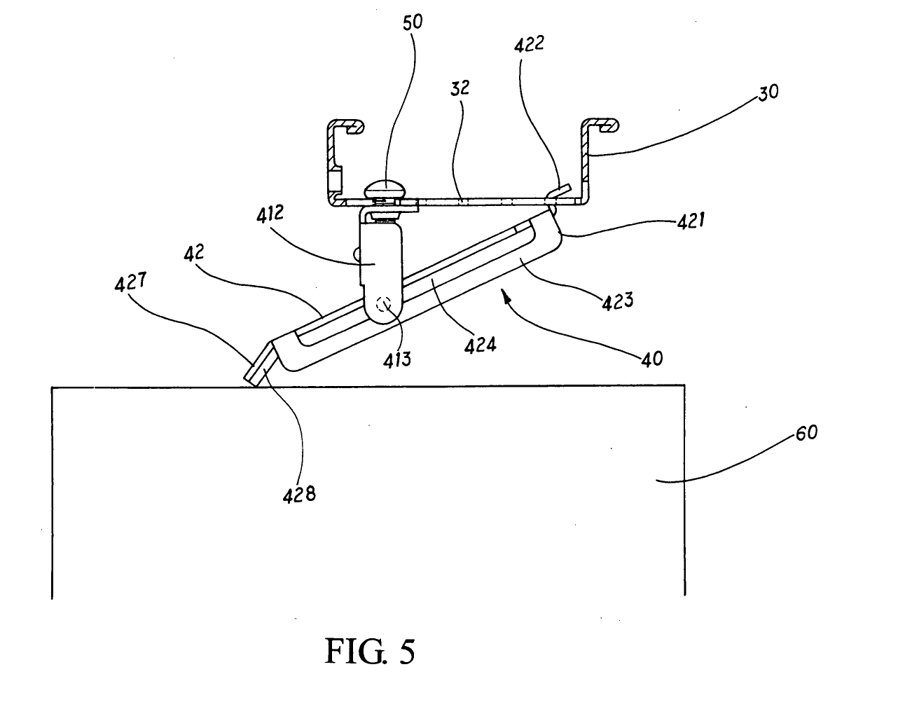

With reference to FIG. 5, it illustrates that the press unit 40 presses an interface card 60. In that, the rotary shaft 413 of the bracket 41 enters into the sliding groove 424 from the opening 425 of the suspending arm 42 to be combined as a press unit 40. The bracket 41 is locked to the guide channel 31 of the press stripe 30 by using a locking unit 50. The press unit 40 can slide along the guide channel 31 to search for a position for pressing the interface card 60 and then is fixed therein. The ear 422 of the suspending arm 42 is inserted to an adjacent slot 32a. The locking unit 50 serves to lock the press stripe 30 and the bracket 41 so as to the interface card 60 is firmly secured.

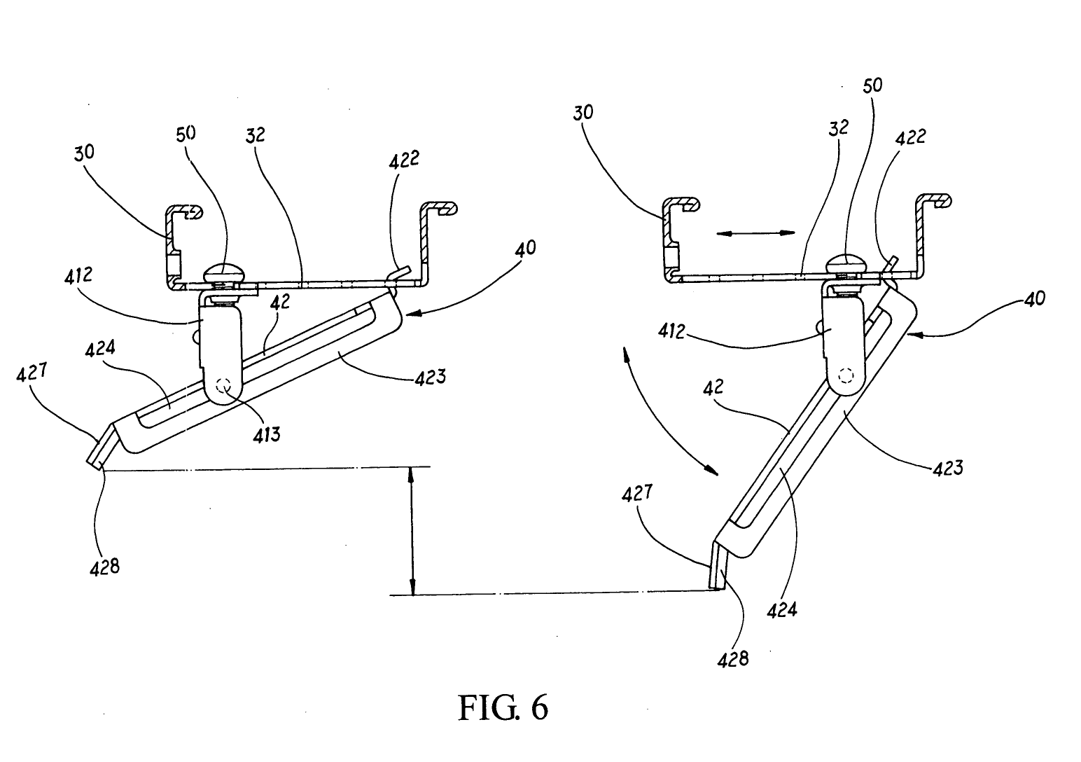

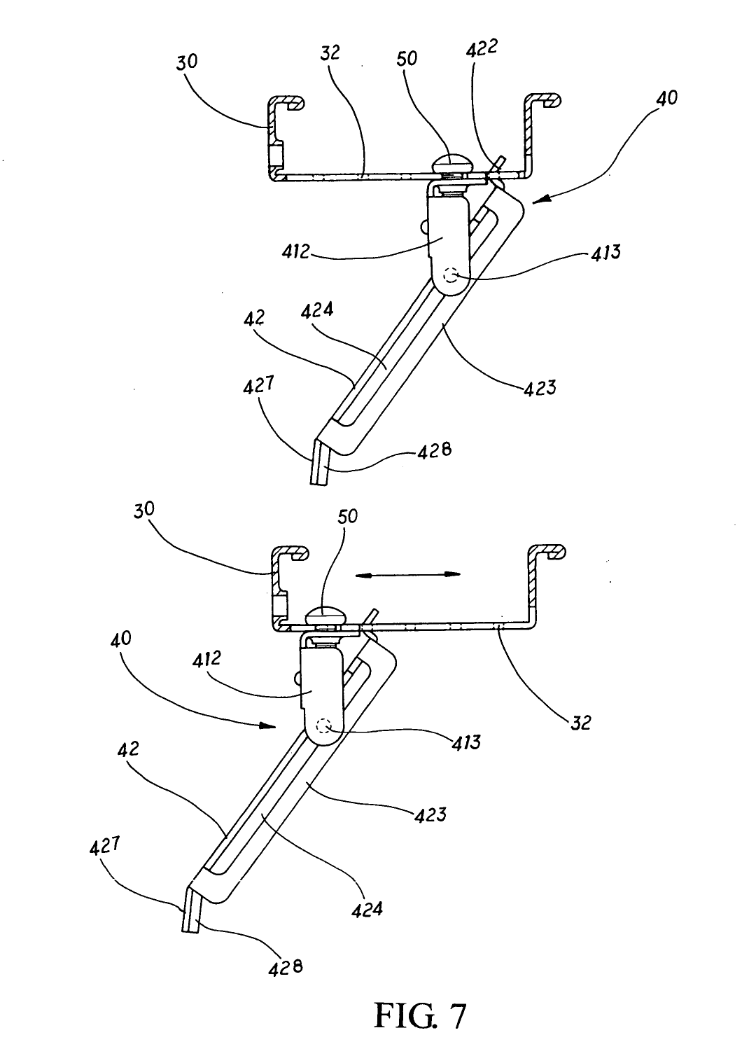

With reference to FIGS. 6 and 7, it illustrates that the present invention can slide continuously. The guide channel 31 of the press stripe 30 causes the press unit 40 can move in the press stripe 30. When the press unit 40 is inclined to the press stripe 30, the movement of the bracket 41 will cause the ear 422 of the suspending arm 42 to be inserted into different slot 32. The extension 427 will search for a proper position to press the interface card (FIG. 7). Similarly, the press unit 40 can be lifted or descent according to the specification of the interface card. That is, the rotary shaft 413 of the bracket 41 slides in the sliding groove 424 of the suspending arm 42 so that the suspending arm 42 is moves to a different elevation so as to adjust the orientation of the press unit 40.

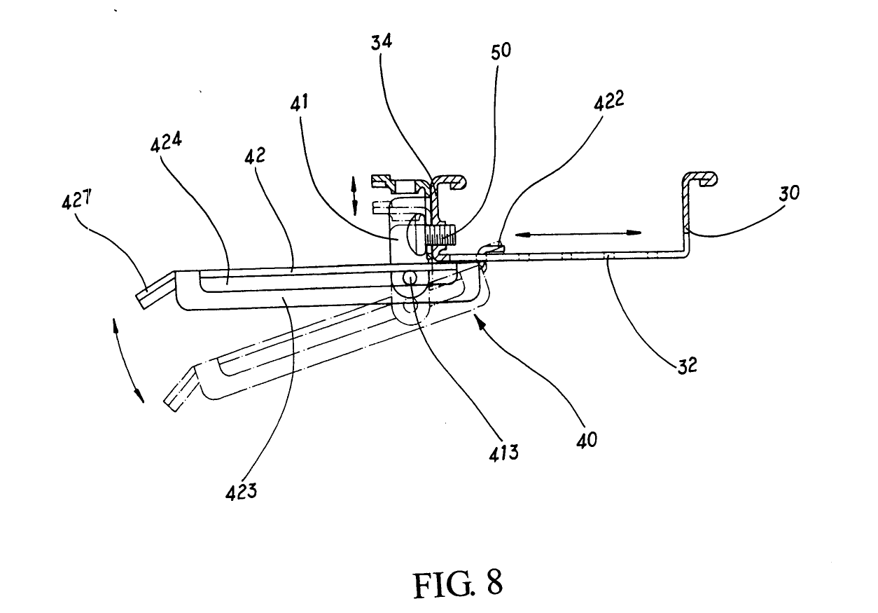

Referring to FIG. 8, another embodiment of the present invention is illustrated. Other than installing the press unit 40 at the lower surface of the guide channel 31 of the press stripe 30 (see FIG. 6), in this embodiment, the press unit 40 can be engaged to the long groove 341 at the first wall 34 of the press stripe 30 so that the press unit 40 can move upwards or downwards. In this embodiment, the bracket 41 is adhered to the first wall 34 of the press stripe 30. The locking unit 50 serves to fix the bracket 41, the position of the press unit 40 is adjusted by the rotary shafts 413 of the suspending arm 42 to slide in the sliding groove 424. Meanwhile, the bracket 41 also moves in the long groove 341. The ear 422 is inserted into an adjacent slot 32. Finally, the locking unit 50 is locked. However, in this embodiment, the locking operation can be performed after all the components are installed to predetermined positions.

The present invention is thus described, it will be obvious that the same may be varied in many ways. Such variations are not to be regarded as a departure from the spirit and scope of the present invention, and all such modifications as would be obvious to one skilled in the art are intended to be included within the scope of the following claims.

What is claimed is:

1. A press stripe device for a computer interface card comprising:
a casing body;
at least one press stripe locating above the casing body; the press stripe having a plurality of guide channels; each of two sides of the guide channel having a plurality of slots;
at least one press unit formed of a bracket and a suspending arm which is pivotally installed to the bracket; the bracket having a block corresponding to the guide channel and at least one downward extending rotary shaft; the suspending arm having an ear corresponding to the slot of the press stripe and sliding grooves at two sides thereof; and
wherein the press unit is engaged to the press stripe by the block being locked to a lower side of the press stripe so that the bracket is moveable to drive the suspending arm of the bracket.

2. The press stripe device for a computer interface card as claimed in claim 1, wherein a front end of the suspending arm of the press unit has an extending end and a bottom of the extending end has a pad.

3. The press stripe device for a computer interface card as claimed in claim 1, wherein when the suspending arm of the press unit presses an interface card, a locking unit serves to lock the press unit to the guide channel of the press stripe.

4. The press stripe device for a computer interface card as claimed in claim 1, wherein the bracket of the press unit has a short groove.

5. The press stripe device for a computer interface card as claimed in claim 4, wherein the bracket is adhered to the first wall of the press stripe; a locking unit serves to fix the bracket.

6. The press stripe device for a computer interface card as claimed in claim 1, wherein the press stripe has a second wall; the second wall has a through hole for receiving the block.
